(19) United States
(12) Patent Application Publication
(10) Pub. No.: US 2017/0170826 A1
(43) Pub. Date: Jun. 15, 2017

(54) OPTICAL SENSOR BASED MECHANICAL KEYBOARD INPUT SYSTEM AND METHOD

(71) Applicant: David L. Henty, Newport Beach, CA (US)

(72) Inventor: David L. Henty, Newport Beach, CA (US)

(21) Appl. No.: 15/377,802

(22) Filed: Dec. 13, 2016

Related U.S. Application Data
(60) Provisional application No. 62/267,035, filed on Dec. 14, 2015.

(51) Int. Cl. H03K 17/969; G06F 1/16

(52) U.S. Cl. CPC H03K 17/969; G06F 1/1669; H03K 2217/94104; H03K 2217/94112

(57) ABSTRACT

A system and method for mechanical keyboard input to a computer system is disclosed. In one aspect the present invention provides a system and method for providing optical sensor based key input detection on a keyboard having a plurality of mechanically movable keys and tactile key entry. The keyboard may be functionally completely passive merely providing tactile feedback and reference markers for the optical sensor system. In another aspect the present invention provides touch sensing combined with the above noted keyboard key detection system and method.

### RELATED APPLICATION INFORMATION

The present application claims priority Under 35 USC 119(e) to provisional application Ser. No. 62/267,035 filed Dec. 14, 2015, the disclosure of which is incorporated herein in its entirety.

### BACKGROUND OF THE INVENTION

1. Field of the Invention

The present invention relates to keyboards and computer systems having keyboards. The present invention further relates to systems and methods of control of computer systems including keyboard and touch control systems and methods.

2. Description of the Prior Art and Related Information

Many keyboard input systems are known in the art and include mechanical as well as touch surface keyboard approaches. Mechanical keyboards are typically preferable due to the feel desired for rapid text input. The keyboard may be a connected part of a computer system, such as in a laptop computer, or separate. In the later case wireless input is desirable but requires a power source for the keyboard, namely a battery in most cases. Keyboards may also be detachable from the rest of the computer, as in a variety of so called hybrid laptop computers which combine detachable keyboards and tablet designs. In such hybrid designs both detachable mechanical and electrical connections between the keyboard and tablet are typically provided. In particular the detachable electrical connection to the keyboard may be problematic and/or limiting in configuration of the system. Touch control for mouse type computer control is common in laptop computers and in detachable or hybrid computers. Such systems suffer from similar coupling and power issues noted above for the keyboard.

Accordingly, combined keyboard and computer systems have been limited by requiring separate keyboard batteries and/or poor ergonomics, mechanical complexity or lack of touch control.

### SUMMARY OF THE INVENTION

In one aspect the present invention provides a system and method for providing optical sensor based key input on a keyboard having a plurality of mechanically movable keys and tactile key entry.

In another aspect the present invention provides touch sensing systems combined with the above noted system and method.

Further aspects of the invention are disclosed in the following detailed description.

### BRIEF DESCRIPTION OF THE DRAWINGS

FIG. 1 is a drawing of a computer system with a wired or wireless keyboard having integrated touch control in accordance with the present invention.

FIG. 2 is a flow diagram illustrating entry and exit of touch control mode of operation of the system of FIG. 1.

FIG. 3 is a cutaway view of the keyboard of FIG. 1 illustrating the smooth surface of the keyboard adapted for touch control.

FIG. 4 is a cutaway view of the keyboard of FIG. 1 illustrating the smooth surface of the keyboard adapted for touch control in an alternate embodiment.

FIG. 5 is a cutaway view of the keyboard of FIG. 1 illustrating an angled IR LED and an angled reflector providing a low profile keyboard edge for providing the touch sensing beam.

FIG. 6 is a top partial cutaway view of the keyboard of FIG. 1 illustrating an embodiment employing two IR LEDs and plural angled reflectors for providing the touch sensing beam.

FIG. 7 and FIG. 8 are schematic drawings of the keyboard illustrating an alternate embodiment of the LED touch position detection system.

FIG. 9 is a schematic drawing of the sensing area relative to the keyboard.

FIG. 10 is a schematic drawing of a portable computer employing touch sensing in accordance with the invention.

FIG. 11 is a cutaway view of the keyboard of FIG. 1 showing keys with markers for key travel detection.

### DETAILED DESCRIPTION OF THE INVENTION

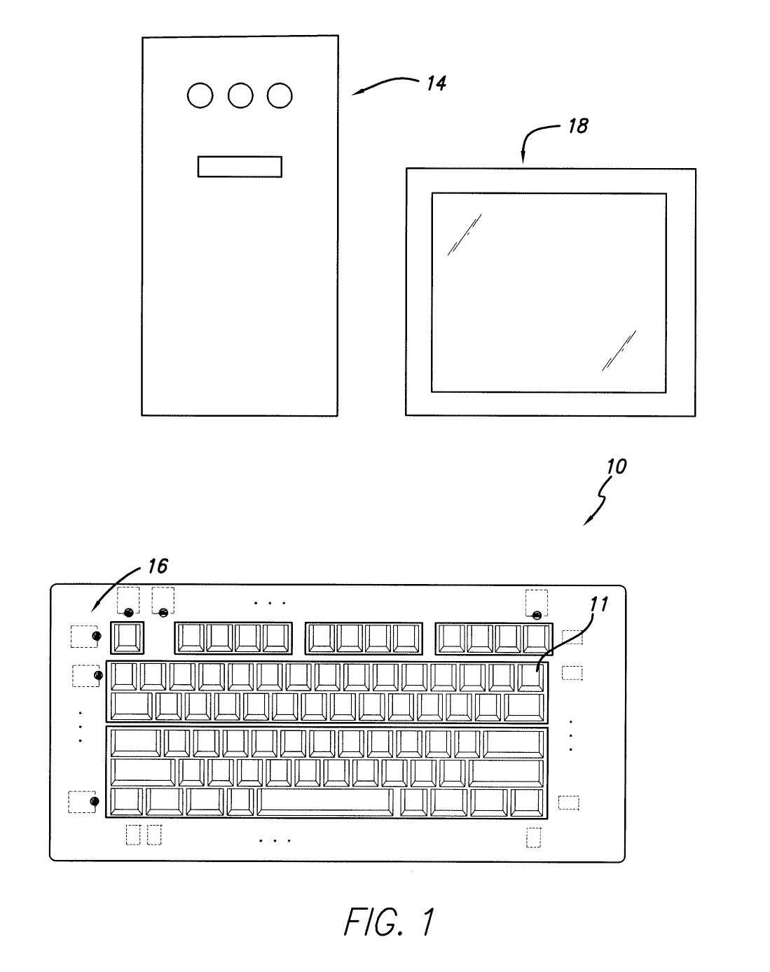

Referring to FIG. 1, a computer system incorporating a wired or wireless keyboard 10 with integrated touch control is illustrated. Keyboard 10 may be a QWERTY keyboard as one example. The computer system as illustrated also includes a housing 14 which includes the processor, hard disk drive, and other components in a conventional computer system, as well as a receiver to receive wireless key and touch control transmission from keyboard 10 in a wireless keyboard embodiment. The computer system also includes a monitor 18 which may be a CRT or LCD type of display or other display known in the computer art. The computer system may also comprise a laptop system with keyboard 10 integrated with a display and motherboard in an embodiment which is equally implied herein.

The system employing the keyboard may also comprise an entertainment system as described in the U.S. Pat. No. 6,094,156, incorporated herein by reference. Such an entertainment system may include a game system and some or all of the keys game control keys and provide touch control game operation as well, employing a touch control input as described below. Also, a variety of computing devices such as so called internet appliances and other desktop and portable systems may employ the invention.

The keyboard includes plural separate keys 11, for example in a conventional QWERTY layout, and a touch control area overlapping the keys as defined by touch position sensing elements 16. In a preferred embodiment these elements 16 comprise an array of IR LEDs and opposed IR sensors arranged around the perimeter of the keys. Such touch sensing systems are known for touch screen applications and are available commercially from a number of suppliers. Accordingly, details of their operation will be omitted. Keys 11 are recessed slightly to allow the IR beams to pass over the top of the keys to allow detection of finger position during touch control operation as one or more fingers are brushed over the surface of the keys. When not in touch control mode the keys 11 function as a conventional keyboard providing text input as well as other standard keyboard key inputs. In an alternate embodiment sensing elements 16 may comprise one or more cameras and an IR source with keys 11 made of an IR transmissive but visible light opaque material. The cameras are configured to image the keys from below and will detect finger position by scattered IR light transmitted through the keys. Camera based position detection systems using IR are also known from touch screen applications. Suitable low cost IR transmissive and optically opaque materials are also well known, for example as used in IR windows in remote controls, which may be used for the keys 11 in such an embodiment. Alternatively, a deformable touch sensitive membrane may be provided over the mechanical portion of the keys and provide touch position detection. Such deformable touch sensors are known in the art.

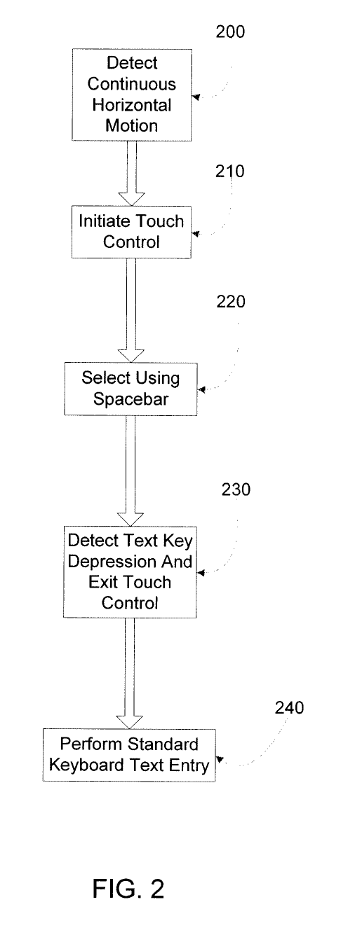

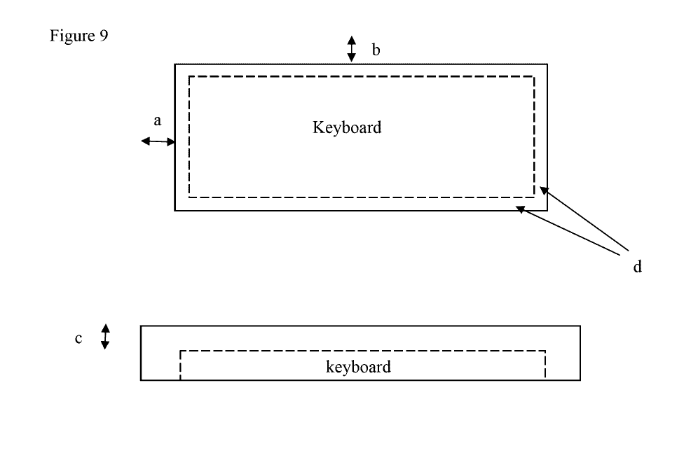

FIG. 2 is a flow diagram illustrating entry and exit of touch control mode of operation of the system of FIG. 1. Preferably automatic entry and exit of touch control operation is provided along with dual functionality of one or more keys on the keyboard, for example the spacebar and/or enter key. At 200 a motion indicating desired touch control is detected. This is a motion distinct from normal keyboard use and may preferably comprise a continuous horizontal motion over plural keys. The motion may also require a unique aspect such as a circular motion or other distinctive motion of a finger or two fingers over the keys. When this motion is detected touch control is initiated at 210. Alternatively a specific key not used for text entry may be allocated to entry of touch control mode. When touch control mode is entered one or more keys 11 are preferably reassigned. For example the spacebar may be reassigned as a mouse left select key and the enter key reassigned as a right select key. Alternatively all keys within the touch area may be reassigned as a select function so a user can move around the screen interface using touch sensing and select without moving the hand. Use of such one or more reassigned keys is illustrated at 220 in the flow diagram. The reassigned key(s) are preferably located outside of the virtual sensing area (see discussion of FIG. 9 below). The specific key(s) reassigned may be user selectable. When in touch control mode multi-touch control may also be initiated with two finger motion providing various control over the display such as zoom out and in, drag, rotate, etc as well known and supported in various operating systems and applications. At 230 the touch control mode is exited by detecting operation of any text key 11 or a specific key assigned to exit the touch mode, such as alt, ctrl or an f function key. Standard keyboard use then resumes at 240 and the spacebar and/or enter key or other reassigned key is returned to normal functionality. In this way rapid entry and exit of touch mode may be provided and easy selection with no added space for a touch pad or special mouse select buttons. (Alternatively, however, separate left and right click buttons such as in a conventional trackpad may be provided, for example at the bottom of the keyboard.) Also, due to the full use of the keyboard area multi-touch control may be easily provided.

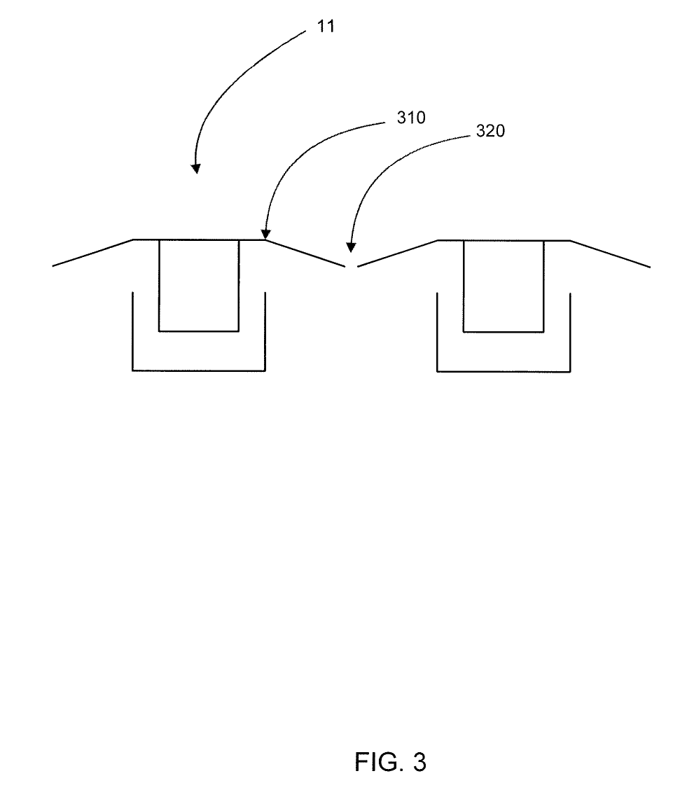

FIG. 3 is a cutaway view of a portion of the keyboard of FIG. 1 illustrating the smooth surface of the keyboard adapted for touch control. The text keys forming the majority of the touch surface area may be conventional in pitch and activation, in the illustrated implementation being a keycap and slide tube configured over a membrane bubble key switch (not shown) as in conventional desktop keyboards. Alternatively, a scissor switch or other conventional key support and activation implementation may be employed. The key cap design differs from conventional keys in that a smooth transition 310 is provided between the top of the key cap and bezel which transition preferably has a radius for a smooth feel rather than an abrupt edge. Also a flat top surface is provided as opposed to a cupped surface as in conventional keycaps which have a shape to correspond to a curved finger tip. Also a shallow bezel recess from the surface is provided (difference in height between point 310 and key split point 320). For example about a 1-2 mm recess (or less) is provided. This provides a smoother surface feel for touch operation. A key travel of about 2 mm may also be provided. If the recess is reduced to zero a flat overall surface is provided retaining inter key gap 320. For standard 19 mm pitch (center to center spacing) the key cap surface would then be about 19 mm (depending on tolerance for inter key gap 320). Alternatively, in this case of no bezel, a slight increase in key pitch may be provided to avoid adjacent key touching for some users, for example an increase from standard 19 mm center to center key pitch may be provided up to about 23 mm. Key travel of at least about 2 mm is preferably retained even for zero recess, however.

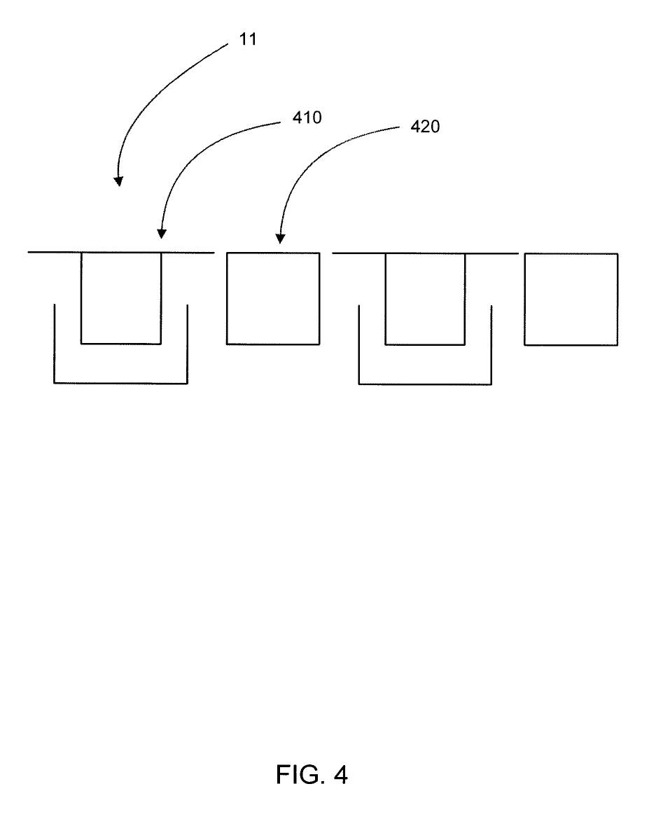

FIG. 4 is a cutaway view of the keyboard of FIG. 1 illustrating the smooth surface of the keyboard adapted for touch control in an alternate embodiment. In this embodiment a flat surface is provided while avoiding inter key interference even for a standard key pitch (19 mm) by providing a smooth slightly deformable insert 420 between the keys. For example, key cap surface 410 may be about 15 mm wide and insert about 4 mm wide providing a total center to center key pitch of 19 mm. Alternatively, key cap surface 410 may be about 17-18 mm wide and insert about 1-2 mm wide providing a total center to center key pitch of 19 mm. Also, as in the prior embodiment a slightly greater key pitch than standard may be provided, for example, a top surface 410 of about 19 mm, an insert of about 2 mm and a total key pitch of 21 mm. As in the prior embodiments a shallow key travel of about 2 mm is preferably employed. The insert 420 shown may be part of a single membrane or deformable layer insert adapted to conform to a bezel free key layout. Such a deformable layer may be a touch sensitive membrane and provide touch position detection by interpolation or may be provided over the mechanical portion of the keys. Such deformable touch sensors are known in the art. Depending on the specific touch sensitive membrane and depth of the key travel, in the latter case the membrane may not deform smoothly at key corners. In this case the touch sensitive membrane may be provided in strips, for example individual strips extending along key rows (or possibly columns or other key groupings). Also folds may be provided in the inter-key spaces to allow greater bending distance of the membrane. In either case the touch sensitive strips or portions may provide continuous touch position detection by interpolation. The use of interpolation in a discontinuous touch sensing surface and implementation details are described in more detail in U.S. Pat. No. 9,478,124, the disclosure of which is incorporated herein by reference in its entirety. In the case of such touch sensing strips or sections these may be attached to another more flexible membrane to provide a continuous touch surface if desired.

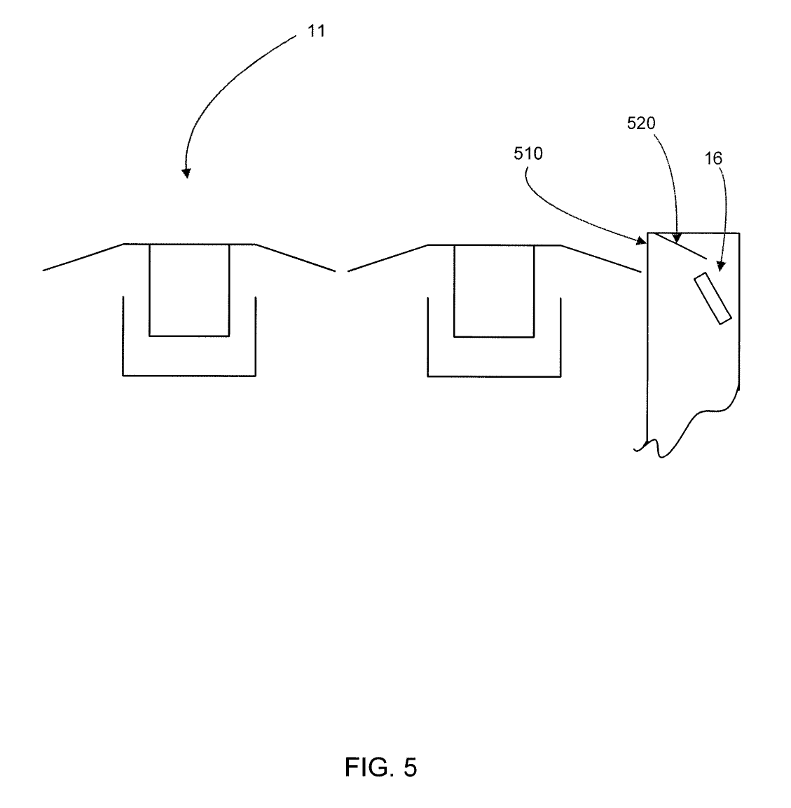

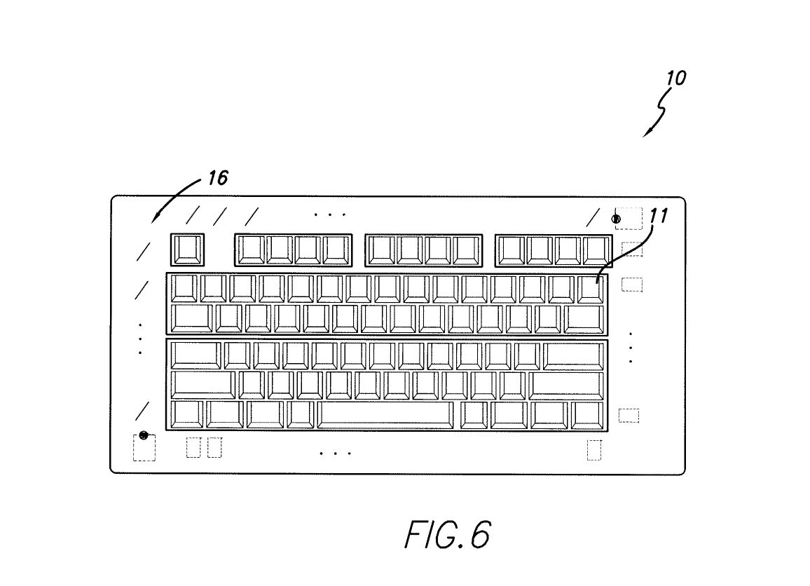

FIG. 5 is a cutaway view of an edge portion of the keyboard of FIG. 1 illustrating an angled IR LED 16 and an angled IR reflector 520 providing a low profile keyboard edge 510 for providing the touch sensing beam. For example, an edge 510 of about 2-4 mm above the key surface may be provided even for LEDs of greater diameter. Also, more space is available for LED driver circuitry. A similar reflector may be used for the IR receiver with a suitable angled receiver. Therefore, an annular reflective strip around the keyboard may be provided. Alternatively, plural angled reflectors may be provided oriented at an angle to horizontal and vertical so two side pointing LEDs may be reflected to plural receivers along each of the two edges. This may employ a partial reflector at each position or an LCD switched reflector at each location. This embodiment is illustrated in FIG. 6. This may provide further space savings and potentially cost savings.

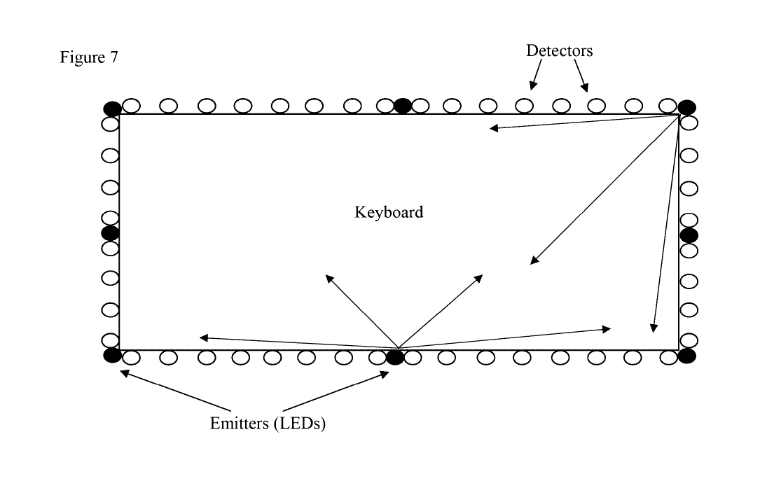

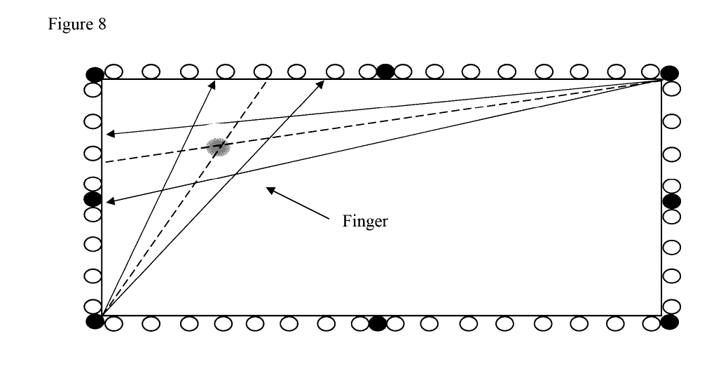

Referring to FIG. 7 and FIG. 8 an alternate embodiment of the LED touch position detection is illustrated. The embodiment uses infrared LEDs and detectors as in the prior embodiments but uses fewer, wider angle LED emitters, and fewer receivers. The desired resolution is nonetheless achieved by using pulsed LEDs and the timing information to derive direction information. Infrared emitters (LEDs) are located at multiple (2+) locations around the keyboard with 8 shown in the illustrated embodiment located at the four corners and center of each side. The corner emitters will have approximately 90 degree beam angle or greater while the side emitters have a wider beam angle preferably about 180 degrees or greater. Detectors are also located at multiple locations around the keyboard perimeter (24 being illustrated). Emitters are pulsed one at a time in sequence. The response at each detector is stored for each pulse. The time of the detector signal thus corresponds to a specific LED and hence direction. By rotating the LED activation around the keyboard in sequence and storing detected signals a series of directions vs signal strength may be derived as shown in FIG. 8. Where a finger blocks the path of an emitter, the response seen at one or more detectors is lower. Once all emitters have been pulsed, a processor analyzes the data and calculates the position of the finger(s), and moves an on-screen cursor accordingly.

As one specific example, the frequency of each cycle shall be 100 Hz. Each cycle shall comprise data from each emitter (LED) activated in turn. Therefore, for e.g., 8 LEDs the LEDs would be pulsed to provide individual detector timing windows at 800 Hz. The individual LED pulse duration is preferably much shorter than a detection window however to provide clear discrimination between LEDs in the time domain. The LEDs may be identified starting with the number 1 for the top left LED, incrementing in a clockwise direction. LEDs shall be activated in order starting with number 1. The data for each LED shall include data from each detector. The detectors similarly may be identified starting with the number 1 for the top left sensor, incrementing in a clockwise direction. Sensor data shall be reported in order starting with number 1. The detector data shall be an 8 bit level of intensity. Noise should be <1 bit.

Assuming the detector response can be converted to suitable levels, e.g. 256 intensities, weighted interpolation may be employed to achieve cursor resolution several times that of the number of detectors. That is, as shown in FIG. 8, the variation in signal due to the finger shadow is greater for the center detector (shown between the two lines corresponding to boundaries of the finger shadow) than the two detectors on either side. This variation is weighted between the detectors to derive a position to greater accuracy than the simple number of detector locations. For example, a normalized center of gravity calculation may be employed to provide the weighted interpolation. Assuming e.g. 256 intensities, weighted interpolation may be employed to achieve cursor resolution about 10 times that of the number of detectors. This in turn allows a reduction in number of detectors for a desired accuracy with attendant cost and space savings.

Although finger detection is shown based on finger shadow detection, in an alternate implementation reflected IR may be detected to derive finger position. The position location processing will be more complex and must be modified accordingly. However, this approach allows use of a linear configuration of emitters and detectors as opposed to a circumferential configuration as illustrated.

The above processing to derive finger position may be implemented in the laptop microprocessor if the keyboard is configured in a laptop, or in the PC processor if implemented as a separate keyboard, to reduce cost and the output of the detectors may be provided via a USB protocol or may emulate a standard serial device and work with e.g., standard Windows serial driver, appearing as a COM port. Alternatively, finger position processing may be done in a dedicated processor chip.

The present invention may be used to implement direct position control of the computer GUI interface such as in a touchscreen computer or may provide motion control such as in a conventional mouse control. In the former case the touch sensing area preferably has the same aspect ratio as the computer screen to mirror the screen on the keyboard. This sensing area will therefore typically not match the keyboard which will have a different aspect ratio and size and a boundary area of the keyboard outside the sensing area with keys will be provided. The PC processor communication protocol may include command(s) to allow the active sensing area to be defined by the user or for different screens by an OEM integrator. The active area will be defined as top, left, width, height, in percentage units, where the full height of the keyboard is considered 100% in the vertical direction, the full width of the keyboard is considered 100% in the horizontal direction. This requirement is to allow the aspect ratio of the sensing area to be matched to the screen aspect ratio, and to allow keys outside the sensing area to be used for clicking etc. Each of these may vary e.g., from 50 to 100%. The sensing area relative to the keyboard is schematically illustrated in FIG. 9. Size: Height, width of sensing area will vary according to size of keyboard and aspect ratio of the computer screen. A typical size will be 15.0″×4.5″. Thickness of the sensing mechanism (FIG. 9 distances a and b) will preferably not exceed 7.0 mm. Gap between keyboard and sensing mechanism (FIG. 9 distance d) will preferably not exceed 3.0 mm. Height above key caps (FIG. 9 distance c) will preferably not exceed 5.0 mm.

In a further aspect the control mode may be selected by a user to switch between direct position control and motion or relative mouse type control. The communication protocol with the PC processor therefore preferably includes command(s) to switch between absolute and relative coordinates. In relative coordinates mode, the keyboard behaves like a mouse, with finger movement moving the cursor relative to its current position. In absolute coordinates mode, the keyboard behaves like a touchscreen or drawing tablet, with absolute finger position within the sensing area corresponding to a fixed cursor position on screen. The keyboard may also incorporate a conventional track pad which is used for conventional mouse control.

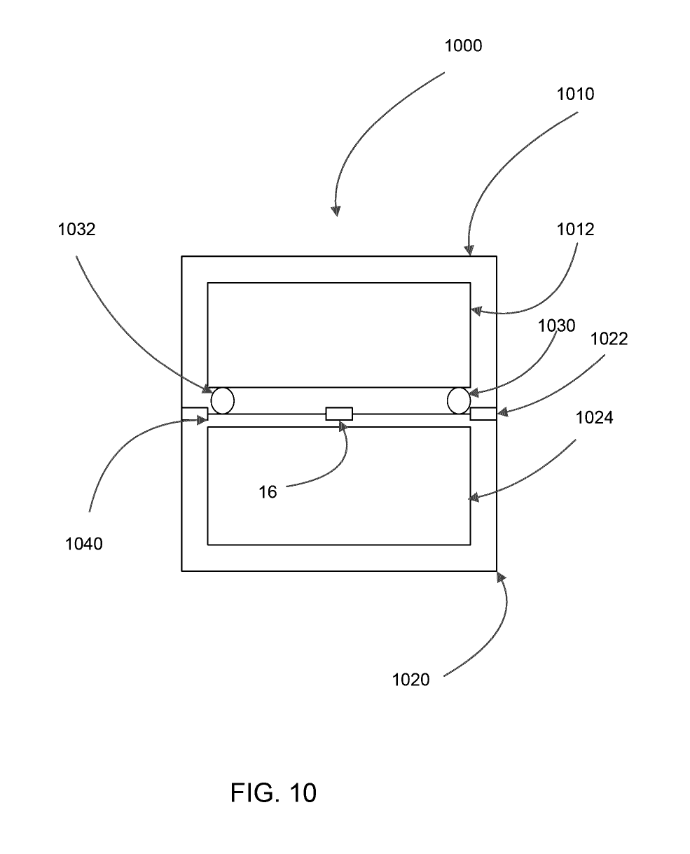

Referring to FIG. 10 a portable computer is illustrated, such as a laptop or notebook computer, employing the present invention. The computer includes a display screen section 1010 with screen 1012 coupled to keyboard section 1020 via hinges 1022. The illustration in FIG. 10 is meant to illustrate these sections as approximately perpendicular. Keyboard section 1020 includes a keyboard 1024 with mechanically activated keys configured with substantially flat key caps and very small interkey gap for easy sliding of fingers thereover as described above. A touch sensing system is provided with a touch sensing area within keyboard 1024 which mirrors screen 1012 as described above, e.g., in relation to FIG. 9. This sensing system may be configured in the perimeter portion of keyboard section 1020 as in the embodiments described above. Alternatively some or all of the sensing system may be configured in the screen section 1010. In particular, in one embodiment cameras 1030, 1032 are provided in the bottom of screen section 1010 and image the surface of the keyboard to detect touch location by detecting finger location in a narrow vertical field of view above the keys and triangulating touch position. Such systems are known and the techniques for touch location are known and accordingly need not be described in detail herein. For example U.S. Pat. No. 7,692,625 the disclosure of which is incorporated herein by reference in its entirety. However, in the present implementation in the portable computer screen section as shown the cameras' 1030, 1032 pointing direction and field of view will change as the screen angle is adjusted. For example, users may often adjust screen angle by as much as +/−30 degrees due to varying conditions of use, i.e., between about 60 degrees and 120 degrees relative to horizontal (or keyboard plane). The present invention provides an adjustment system which detects the screen angle and adjusts the camera field of view to allow camera based touch location. In one embodiment each of cameras 1030, 1032 will be mounted in screen section 1010 at a location substantially flush with keyboard section 1020 surface and pointing directly toward the keyboard section when the screen is vertical. The cameras may employ reflected IR detection in which case one or more IR emitters are mounted to the screen section or hinges and the cameras would employ IR filters. Cameras 1030, 1032 each incorporate a lens providing a vertical field of view of at least about 60 degrees, or more generally about 60-90 degrees, to accommodate the possible change in screen position. An angle sensor 1040 is configured in a hinge 1022 or in the screen section immediately adjacent a hinge and detects screen angle deviation from a nominal operational position, normally 90 degrees to the keyboard surface. This angle offset is provided to the camera image processor which adjusts the region of interest of the camera image to the portion corresponding to the keyboard surface, i.e., moving the image region of interest vertically up or down with angle offset plus or minus from nominal. Camera based touch sensing systems conventionally employ a dedicated processor for image processing in which case the angle offset is provided to this processor. However, in a preferred embodiment the present invention provides a deviation from this dedicated processor approach and employs the computer processor to perform the image processing and triangulation algorithm for touch location determination. In this case the angle offset information is provided to the computer processor for use by the image processing algorithm. Alternatively, or in combination with the angle sensor, a distinctive fiducial mark may be detected on the keyboard section preferably adjacent the screen section. In combination, the detection of an angle change by the sensor may initiate a recalibration algorithm within the image processing algorithm to locate the marker and adjust the region of interest corresponding to the keyboard. Alternatively this may comprise a fine adjustment after a coarse adjustment using the angle sensor. In an embodiment with IR detection the fiducial mark may be replaced with an IR emitter which is turned on for a brief time, for example under a second, for calibration when the screen angle is changed. In another embodiment the cameras 1030, 1032 may be configured in hinges 1022 in which case they would remain fixed relative to the keyboard while not interfering with keyboard look or layout.

In another embodiment some portion of the LED emitter detector touch sensing system 16 described above may be mounted in hinges 1022 or in a portion of the screen section. In particular the embodiment described in relation to FIGS. 7 and 8 may use a reduced number of emitters and detectors enabling use of hinges 1022 to provide the top portion of the system 16 reducing impact on keyboard surface features for implementing the touch sensing system. The portion of system 16 may also be mounted in the screen section in which case means may be provided to compensate for screen angle, including mechanical means for changing tilt of the emitters or detectors or means for adjusting an aperture or lens effective direction.

It will be appreciated that sufficiently accurate detection of finger (or key) motion in the key depression direction may allow key activation detection without any electrical connection to the mechanical key assembly. That is detection of travel in the amount of the mechanical key travel distance will signal key activation. This may thus provide a battery free tactile keyboard. The keyboard may simply comprise a housing with movable keys supported therein in any conventional manner (such as generally illustrated by keys and housing of FIGS. 1 and 10) with a tactile feel provided in a conventional manner, for example, by a membrane with deformable bubbles as in conventional keyboard designs. An on board processor or key press detection circuitry are not needed Therefore, no power need be supplied to the keyboard nor are batteries neede. In the case of a laptop computer this will avoid running wires through the hinge(s). Also, a detachable keyboard and display may be more readily provided facilitating so called two in one devices. Other applications include tablet keyboard accessories, or other wireless keyboard applications. Correlation of the finger position with a specific key may be achieved by matching the image to a template once keyboard overall position is known using fiducial reference marks on the keyboard as described above. That is, once the relative position of the keyboard to the sensing system is known from detecting fiducial reference marks (either on the fly or in a brief calibration step), a stored keyboard key layout or template may be used to correlate a detection position with a specific key. Alternatively, the key letters may be identified from the image using OCR and the occluded key being depressed determined from adjacent visible keyboard letters.

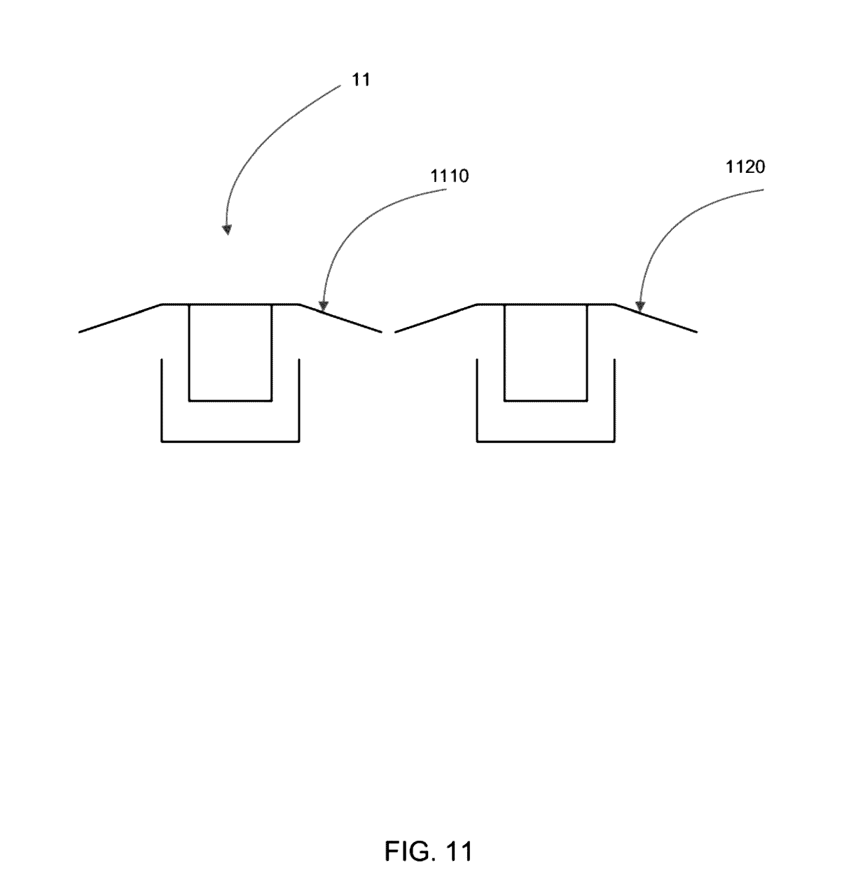

Alternatively, the key letters may be identified by marking the edge portion of each key or side bezel facing the camera (or other front top and edge key portion in the camera view) with a unique identifier such as a bar code. This mark would be configured to not be occluded by the user's finger(s) or adjacent key(s) based on camera position and key layout. Such mark could be a visible mark or an IR reflective mark if an IR emitter is employed in the display and/or camera. The use of a mark on each key can also facilitate accurate detection of travel in the key depression direction corresponding to mechanical key activation and desired tactile feel. Specifically, the marker on each key may be positioned on the key side so that when fully depressed the marker disappears from the camera view behind the key in front or the key receptacle (which may be a plastic plate surrounding the keys as known in various keyboard designs). Alternatively, vertically oriented lines or other measuring marks may be provided on each key so that vertical travel can be measured by line movement. Therefore, each key may have a first identifying mark such as a bar code and a second measurement mark set to measure key travel, for example one oriented horizontally and one vertically, or a single mark such as a segmented horizontal line encoding the key and allowing position measurement. Also, a mark may be provided on a key in front of another key to denote the limit of travel of the key behind. For example, when a mark on the depressed key aligns with a mark on the back edge of the front key, key activation may be detected. Key pairs may also have a marker or feature which combine for depression detection; for example, a depressed key feature may appear in a gap between two keys in front of the depressed key. In general, the key orientations relative to each other and to the camera or other sensor may determine the optimal reference mark or features to be employed. Such various marks are illustrated generically by markers 1110 and 1120 in FIG. 11. It should be appreciated these key shapes are highly schematic and many variations in shape and marker position(s) are possible. For example, flat key sides may be provided rather than an angled bezel. For example, one type of “chicklet” style keys may not have any bezel and may simply be flat sided keys which recess into a common plastic key coverplate. Other flat style keys may have flat sides which extend down to a flat bezel. Also, offset or aligned key layouts may be provided. Therefore, many key shapes and orientations may be employed and the marker type and position may vary accordingly. Also, the marker may in some cases be a key edge or other structural feature providing desired key travel information.

Once a key and some reference for vertical key position are determined velocity or a velocity profile over time may also be used to determine a key stroke has been made. For example, if a vertical downward key velocity is detected, which may be compared to a minimum value set by the key activation mechanism (which may simply be a deformable bubble membrane beneath the key which sets the amount of deformation pressure for full key travel corresponding to key activation), then a key activation may be inferred. Alternatively, a velocity profile with a downward velocity which is followed by a transition to zero velocity or a transition to upward motion, may signal a key activation. Suitable detection algorithms following the above detection process flow may be readily implemented in the optical sensing system processor or the computer processor using data from the sensor. Similarly finger motion may be used in the same way to determine key activation, as discussed below.

3D cameras or depth sensing cameras are available which may be used to determine key or finger vertical position and/or velocity for detecting movement corresponding to mechanical key activation. This may be desirable in some implementations.

If the camera or other sensor can detect a user's fingers then another key depression detection approach may simply detect the finger tip image becoming cut off or flattened as the key is depressed. Various optical finger detection systems are known in the art and are used for gesture control of computers and other devices and the related algorithms may be easily modified for the noted detection. Some of these employ depth sensing cameras and associated processors implementing a finger detection algorithm. This finger detection approach may be advantageous where the camera or other sensor is generally flush with the keyboard or at an angle where the keys themselves are not in the field of view. Alternatively, another finger detection approach may exploit the fact that the finger tip position will occupy a wider portion as the key is depressed and an optical touch location sensor such as described above can be employed which can use two dimension touch position information (this approach may also be desirable for an implementation using a depth camera with a limited field of view). That is the finger tip touch position will initially be detected at essentially a point as the key is touched and then will be detected over a substantially larger area as the key is depressed, until generally substantially equaling the size of the key cap. A touch sensor configured to detect finger position over the keys as described in detail above may implement an algorithm comparing successive sizes of a detected touch location to detect key depression in this way. For example, a change from a minimum finger position detection size to approximately 75% of key cap size or more may signal key depression. This approach may employ an initial calibration of a few keystrokes (due to variations in user finger size) to fix the threshold key detection size. If the key is not visible to the sensing system key identification in this approach will require a known position for each key and may use a keyboard orientation detection marker on a visible portion of the keyboard and a stored key layout template as described above. Also, finger velocity detection may be employed in the same manner as key velocity detection described above where the individual key itself is not detectable due to sensor angle. This may be derived from touch area rate of change or directly with a depth sensing camera. Depending on the keyboard membrane or other tactile component, a unique velocity profile will be provided and this may be used if necessary beyond detecting a simple velocity threshold or velocity change. Finger velocity also be combined with shape or touch area thresholds to make key depression detection more robust. Suitable algorithms may be readily implemented in the optical sensing system processor or the computer processor using data from the sensor.

As described above the camera or touch sensors may detect touch input as well. This may be combined with keystroke detection using a single sensor set. This touch input may be in a defined area separate from the keys as in a typical laptop design or may overlap the key area as described above.

Further modifications may be made which will be appreciated from the above teachings and the illustrated embodiments should not be viewed as limiting in nature.

What is claimed is:

1. A computer system, comprising:
a display portion:
a keyboard having a plurality of movable keys, the keys having one or more markers to identify a key position corresponding to key activation; and
an optical sensing system configured to detect the key markers and identify key activation by key marker movement to a position corresponding to key activation.

2. A computer system as set out in claim 1, wherein the sensing system is configured on the display portion.

3. A computer system as set out in claim 1, wherein the markers comprise IR reflective markers and the sensing system includes an IR emitter and one or more IR detectors.

4. A computer system as set out in claim 1, wherein the one or more markers are configured on the keys to disappear from detection by the sensing system when the key is depressed to a key activation position.

5. A computer system as set out in claim 4, wherein the one or more markers are blocked by one or more adjacent keys when a key is depressed to a key activation position.

6. A computer system as set out in claim 4, wherein the keyboard includes a key housing structure adjacent each key and wherein the markers are blocked by the housing structure when the key is depressed to a key activation position.

7. A computer system as set out in claim 1, wherein the one or more markers are configured on the keys to align relative to second markers on adjacent keys when the key is depressed to a key activation position.

8. A computer system as set out in claim 1, wherein the keyboard includes a housing structure adjacent each key and wherein the markers align relative to second markers on the housing structure when the key is depressed to a key activation position.

9. A computer system as set out in claim 1, wherein the sensing system comprises a depth sensing camera.

10. A computer system as set out in claim 1, wherein the markers on each key comprise a first marker providing key identification information and a second marker aligned to provide key depression information when the key is depressed.

11. A computer system as set out in claim 10, wherein the first markers providing key identification information comprise barcodes.

12. A computer system as set out in claim 1, wherein the keyboard has no power supply or input.

13. A computer system as set out in claim 1, wherein the keyboard is detachably mounted to the display portion.

14. A computer system as set out in claim 1, wherein the optical sensing system is further configured to detect touch position on a touch input surface of the keyboard portion.

15. A computer system as set out in claim 1, wherein the optical sensing system detects a velocity profile of the key marker which is employed to detect key activation.

16. A computer system, comprising:
a display portion:
a keyboard having a plurality of movable keys; and
an optical sensing system configured to detect the users fingers and identify key activation by one or more of finger tip shape alteration, finger position, or finger velocity to detect finger movement to a position corresponding to key activation.

17. A computer system as set out in claim 16, wherein the optical sensing system comprises a camera and a processor which implements a finger detection algorithm using data from the camera.

18. A method for detecting key activation in a keyboard having one or more movable keys, comprising:
detecting a marker on a movable key using an optical sensing system;
comparing the marker position to a reference mark or feature on the keyboard corresponding to key movement to a key activation position; and
determining a key activation when the key mark moves to a predetermined position relative to the reference mark or feature.

19. A method for detecting key activation as set out in claim 18, further comprising detecting a second marker on the key to identify the key.

20. A method for detecting key activation as set out in claim 18, wherein the optical sensing system comprises a camera and a processor which implements a finger detection algorithm using data from the camera.
